(19) United States
(12) Patent Application Publication
(10) Pub. No.: US 2015/0255563 A1
(43) Pub. Date: Sep. 10, 2015

(54) METHOD FOR MANUFACTURING A SEMICONDUCTOR DEVICE HAVING MULTI-LAYER HARD MASK

(71) Applicant: United Microelectronics Corp., Hsinchu (TW)

(72) Inventors: Yen-Liang Wu, Taipei City (TW); Chung-Fu Chang, Tainan City (TW); Yu-Hsiang Hung, Tainan City (TW); Man-Ling Lu, Taoyuan County (TW); Cho-Han Fan, Tainan City (TW); Ssu-I Fu, Kaohsiung City (TW); Chen-Ming Huang, Taipei City (TW)

(73) Assignee: United Microelectronics Corp., Hsinchu (TW)

(21) Appl. No.: 14/195,967

(22) Filed: Mar. 4, 2014

(51) Int. Cl. H01L 29/51; H01L 29/78; H01L 29/66

(52) U.S. Cl. CPC H01L 29/512; H01L 29/66795; H01L 29/6656; H01L 29/6653; H01L 29/785; H01L 29/517; H01L 29/518

(57) ABSTRACT

A method for manufacturing a semiconductor device is provided, comprising steps of providing a substrate with an underlying layer formed thereon; forming a gate layer overlying the underlying layer; and forming a multi-layer hard mask layer on the gate layer, and the multi-layer hard mask layer comprising a plurality of material layers and a top hard mask formed on the material layers, wherein the gate layer and the top hard mask contain the same element, such as silicon.

### BACKGROUND

1. Technical Field

The disclosure relates in general to a method for manufacturing a semiconductor device and structure thereof having multi-layer hard mask, and more particularly to a method for manufacturing a semiconductor device with good electrical properties by multi-layer hard mask.

2. Description of the Related Art

A semiconductor device with good electrical performance requires the gates with excellent properties such as complete profiles and sufficient height. The current gate forming process generally suffers from the spacers pull down and the gate height loss during Dual EPI process. Insufficient gate height or incomplete gate profile would have undesirable effect on the electrical characteristics of the device. Also, a nitride layer formed as the hard mask could be laterally exposed due to the pull down spacers. The exposed SiN would be undesirably etched when a chemical agent (such as hot H3PO4) is applied for the removal of the spacers subsequently.

Accordingly, it is desired to develop a method for forming a gate with sufficient height for the manufacturing process, and also solve the problem caused by pull down spacers.

### SUMMARY

The disclosure is directed to a method for manufacturing a semiconductor device and structure having multi-layer hard mask, which is capable of constructing the gate with complete profile and sufficient height, thereby improving the electrical properties of the semiconductor device.

According to the disclosure, a method for manufacturing a semiconductor device is provided, comprising steps of providing a substrate with an underlying layer formed thereon; forming a gate layer overlying the underlying layer; and forming a multi-layer hard mask layer on the gate layer, and the multi-layer hard mask layer comprising a plurality of material layers and a top hard mask formed on the material layers, wherein the gate layer and the top hard mask contain the same element.

According to the disclosure, a semiconductor device is provided, comprising a substrate having plural fins spaced apart from each other; an underlying layer formed on the substrate; a gate layer formed on the underlying layer and covering the fins; and a multi-layer hard mask layer formed on the gate layer. The multi-layer hard mask layer at least comprises a silicon nitride layer formed on the gate layer, an oxide layer formed on the silicon nitride layer, and an amorphous silicon formed on the oxide layer.

### BRIEF DESCRIPTION OF THE DRAWINGS

FIG. 1A-FIG. 10 schematically illustrate a method for manufacturing a semiconductor device according to the embodiment of the present disclosure.

FIG. 2 depicts a cross section view of the structure manufactured by the comparison scheme.

FIG. 3 depicts a cross section view of the structure manufactured by the embodied scheme.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

In the embodiment of the present disclosure, a method for manufacturing a semiconductor device is provided. According to the embodiment, the semiconductor device as manufactured has complete gate profile, thereby possessing good electrical properties. The embodiment of the present disclosure solves the problem of exposure of SiN (one of hard masks) due to the pull-down spacers occurred in the conventional semiconductor device, and also presents the gate layer with sufficient gate height after Dual EPI process.

Embodiments are provided hereinafter with reference to the accompanying drawings for describing the related configurations and procedures, but the present disclosure is not limited thereto. It is noted that not all embodiments of the invention are shown. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

The method of the present disclosure can be applied to various types of semiconductor devices. For example, applicable semiconductor device may comprise field-effect transistor, such as n-channel FET (NFET) and p-channel FET (PFET), and/or fin field electric transistor (Fin-FET). The method of the present disclosure is applicable to a semiconductor device requiring higher gate for more complicated middle end of line (MEOL) process. The embodiment herein illustrates one of the semiconductor devices in applications comprising p-channel Fin-FET and n-channel Fin-FET. However, the present disclosure is not limited thereto.

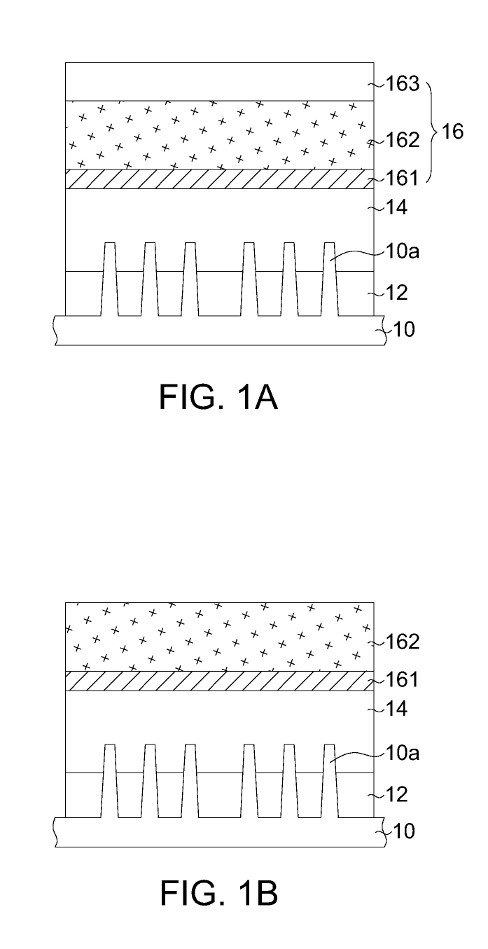

FIG. 1A-FIG. 10 schematically illustrate a method for manufacturing a semiconductor device according to the embodiment of the present disclosure. First, a substrate 10 with an underlying layer 12 formed thereon is provided. The embodiment illustrates, but not limitedly, a semiconductor device having a PFET region and a NFET region, and the semiconductor device comprises Fin-FET. As illustrated in FIG. 1A-FIG. 10, the substrate 10 comprises plural fins 10a spaced apart from each other. A gate layer 14 is formed overlying the underlying layer 12 and covering the fins 10a. In the subsequent procedures, the gate layer 14 is patterned by hard mask and then replaced by metal (i.e. metal gate), the metal gate straddles on three sidewalls of the fins 10a, thereby forming a fin-FET with gate on the three dimensional (3D) fin structure. Since the fin channel between source S and drain D is covered by the gate, three surfaces of the fin 10a could be utilized to provide more current paths.

In the gate etching process of the embodiment, a multi-layer hard mask layer 16 is formed on the gate layer 14. According to the embodiment, the multi-layer hard mask layer 16 comprises a plurality of material layers and a top hard mask formed on the material layers. As shown in FIG. 1A, the material layers include a first dielectric layer 161 formed on the gate layer 14 and a second dielectric layer 162 formed on the first dielectric layer 161. A top hard mask 163 is then formed on the second dielectric layer 162.

According to the embodiment, the gate layer 14 and the top hard mask 163 contain the same element (ex: silicon). In one embodiment, the gate layer 14 and the top hard mask 163 comprise silicon, such as amorphous silicon (a-Si) or polysilicon.

Materials of the gate layer 14 and the top hard mask 163 can be different, or completely identical (such as comprising the same silicon-containing material), which are not particularly limited. In one embodiment, one of the gate layer 14 and the top hard mask 163 can be made of polysilicon while the other is made of amorphous silicon. In one embodiment, the gate layer 14 and the top hard mask 163 are all made of amorphous silicon, or polysilicon. The device with the gate layer 14 and the top hard mask 163 made of amorphous silicon would obtain good profile of gate layer after performing the replacement metal gate (RMG) process.

According to the embodiment, the second dielectric layer 162 can be a dielectric anti-reflective coating (DARC) layer. In one embodiment, the first dielectric layer 161 is a nitride layer, and the second dielectric layer 162 is an oxide layer.

In the subsequent patterning process, the top hard mask 163 is removed as shown in FIG. 1B, and forming the spacers 18 at sidewalls of the stack as shown in FIG. 1C after the top hard mask 163 is removed. After growing silicon germanium (SiGe), the spacers 18 are removed by a suitable chemical solution, such as hot H₃PO₄. If the first dielectric layer 161 comprising nitride were partially exposed during the removal of the spacers 18, it would be damaged and undesirably etched by hot H₃PO₄. According to an embodiment, the spacers 18 fully cover sidewalls of the gate layer 14 and the first dielectric layer 161, as shown in FIG. 10, thereby preventing the first dielectric layer 161 from etching by the chemical solution (ex: hot H₃PO₄) during removal of the spacers 18.

Additionally, the thicknesses of the gate layer 14 and the multi-layer hard mask layer 16 can be determined in an appropriate arrangement, so that at least sidewalls of the first dielectric layer 161 can be fully covered by the spacers 18. According to one embodiment, a thickness of the first dielectric layer 161 is thinner than a thickness of the second dielectric layer 162. For example, a thickness ratio of the first dielectric layer 161 to the second dielectric layer 162 is in a range of about 1:5 to 1:10.

Moreover, in one embodiment, a thickness of the first dielectric layer 161 is thinner than a thickness of the top hard mask 163. Also, in one embodiment, a thickness of the top hard mask 163 is less than half of a height of the gate layer 14.

Also, the thicknesses of the gate layer 14 and the multi-layer hard mask layer 16 can be determined depending on the requirements of practical applications. In one embodiment, the thickness of the gate layer 14 is in a range of about 750 Å˜ about 1350 Å (for example, 1000 Å˜1100 Å). In one embodiment, the thickness of the first dielectric layer 161 (ex: the nitride layer) is in a range of about 100 Å˜200 Å. In one embodiment, the thickness of the second dielectric layer 162 (ex: the oxide layer) is in a range of about 700 Å˜1200 Å. In one embodiment, the thickness of the top hard mask 163 is about 250Å-350 Å, for example, 300 Å.

Several experiments are conducted to investigate the effect of the embodied method on the gate layer. The experimental results have indicated that the semiconductor device manufactured by the method of the embodiment possesses a more complete gate profile and sufficient gate height. Electrical performance of the semiconductor device would be deteriorated due to the unsmooth gate profile and insufficient gate height.

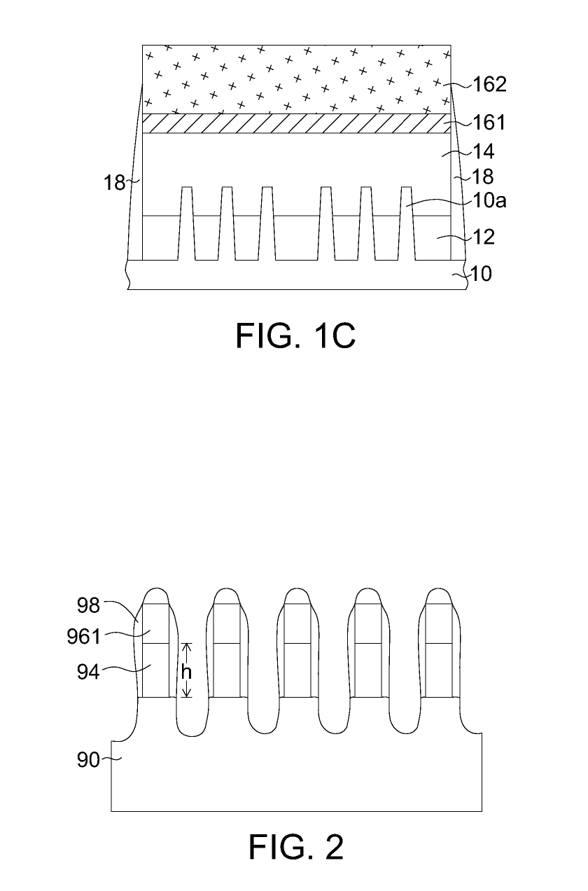

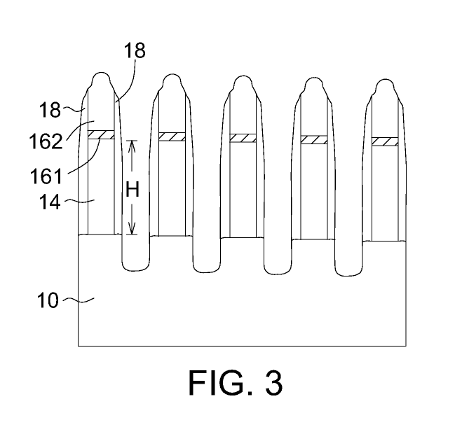

Details of one set of the experiments are described below for showing the gate comparison manufactured by the conventional and embodied schemes. However, it is understood that the embodied scheme below is merely one of applicable methods, and not intended to limit the disclosure. The thicknesses of related layers can be varied without departing from the spirit of the disclosure to meet the requirements of the practical applications and achieve the aims. It is, of course, noted that the thickness arrangements as depicted FIG. 2 and FIG. 3 are depicted only for demonstration of the experiments, not for limitation of the disclosure.

In a comparison scheme provided herein, about 700 Å of a gate layer 94 made of amorphous silicon (a-Si) is formed on a substrate 90, and about 500 Å of a first dielectric layer 961 made of silicon nitride is formed on the gate layer 94, and about 500 Å of a second dielectric layer made of oxide is formed on the first dielectric layer 961. After manufactured by the subsequent patterning steps, the second dielectric layer made of oxide is removed, and spacers 98 are formed. FIG. 2 depicts a cross section view of the structure manufactured by the comparison scheme.

In an embodied scheme provided herein, about 1100 Å of a gate layer 14 made of amorphous silicon (a-Si) is formed on a substrate 10, and about 100 Å˜200 Å of a first dielectric layer 161 made of silicon nitride is formed on the gate layer 14, and about 700 Å˜1200 Å of a second dielectric layer 162 made of oxide is formed on the first dielectric layer 161, and about 300 Å of a top hard mask 163 made of a-Si is formed on the second dielectric layer 162. After manufactured by the subsequent patterning steps, the second dielectric layer 163 is removed, and spacers 18 are formed. FIG. 3 depicts a cross section view of the structure manufactured by the embodied scheme.

In the conventional gate etching process (i.e. comparison scheme), the gate layer 94 is only 700 Å, and merely two layers (i.e. SiN 500 Å and Oxide 500 Å) are formed as the hard mask layer. The conventional scheme suffers from the gate height loss during Dual EPI process. Also, the conventional scheme suffers from the spacers pull down, and the exposed SiN would be undesirably etched if the chemical agent (ex hot H₃PO₄) is applied for the removal of the spacers.

In the embodied method, a thicker gate layer 14 (ex: 1100 Å (thickness H), higher than 700 Å (thickness h) in comparison) is formed, and at least three layers (i.e. a first dielectric layer 161/a second dielectric layer 162/a top hard mask 163) are formed as the multi-layer hard mask layer 16. The first dielectric layer 161 is thinner than the second dielectric layer 162. Furthermore, the gate layer 14 and the top hard mask 163 contain the same element, such as silicon. The result has indicated that the structure manufactured according to the embodied scheme does solve the problem of exposure of SiN (one dielectric layer of hard masks) due to the pull-down spacers in the conventional device. Also, the structure manufactured by the embodied scheme presents a gate layer with sufficient gate height after Dual EPI process. Accordingly, the electrical characteristics of the semiconductor device manufactured by the method of the embodiment are greatly improved consequently.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A method for manufacturing a semiconductor device, comprising:
providing a substrate with an underlying layer formed thereon;
forming a gate layer overlying the underlying layer; and
forming a multi-layer hard mask layer on the gate layer, and the multi-layer hard mask layer comprising:
a silicon nitride layer directly formed on the gate layer;
an oxide layer directly formed on the silicon nitride layer; and
a top hard mask made of amorphous silicon directly formed on the oxide layer,
wherein the gate layer and the top hard mask contain the same element of silicon, a thickness of the to hard mask is thicker than a thickness of the silicon nitride layer and thinner than a thickness of the oxide layer.

2. The method according to claim 1, wherein the gate layer is made of polysilicon while the top hard mask is made of amorphous silicon.

3. The method according to claim 1, wherein the gate layer and the top hard mask are made of amorphous silicon.

4. (canceled)

5. The method according to claim 1, wherein a thickness of the gate layer is in a range of about 750 Å˜1350 Å.

6. The method according to claim 1, wherein the silicon nitride layer is a first dielectric layer directly formed on the gate layer the oxide layer is a second dielectric layer directly formed on the first dielectric layer.

7. The method according to claim 6, wherein a thickness of the first dielectric layer is thinner than a thickness of the second dielectric layer.

8. The method according to claim 6, wherein a thickness ratio of the first dielectric layer to the second dielectric layer is in a range of about 1:5 to 1:10.

9. (canceled)

10. (canceled)

11. The method according to claim 1, wherein a thickness of the silicon nitride layer is in a range of about 100 Å˜200 Å.

12. The method according to claim 1, wherein a thickness of the oxide layer is in a range of about 700 Å˜1200 Å.

13. The method according to claim 1, wherein a thickness of the top hard mask is about 250 Å˜350 Å.

14. The method according to claim 1, wherein a thickness of the top hard mask is less than half of a height of the gate layer.

15. The method according to claim 1, further comprising:
forming spacers at sidewalls of the gate layer, the silicon nitride layer and the oxide layer after the top hard mask is removed
wherein the spacers at least fully cover the sidewalls of the gate layer and the silicon nitride.

16. The method according to claim 1, wherein the semiconductor device comprises a fin field electric transistor (Fin-FET).

17. (canceled)

18. (canceled)
